(19) United States
(12) Patent Application Publication
(10) Pub. No.: US 2025/0364411 A1
(43) Pub. Date: Nov. 27, 2025

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Se Hwan Hong, Gyeonggi-do (KR); Gam Han Yong, Incheon (KR); Min Su Jeong, Incheon (KR)

(21) Appl. No.: 18/671,474

(22) Filed: May 22, 2024

(51) Int. Cl. H01L 23/528; H01L 21/304; H01L 21/311; H01L 23/00; H01L 23/31; H01L 23/48; H01L 23/498; H01L 25/18

(52) U.S. Cl. CPC H01L 23/5283; H01L 21/304; H01L 21/31111; H01L 23/3128; H01L 23/481; H01L 23/49833; H01L 23/49838; H01L 24/16; H01L 24/32; H01L 24/73; H01L 25/18; H01L 24/96; H01L 24/97; H01L 2224/16225; H01L 2224/32225; H01L 2224/73204; H01L 2224/96; H01L 2224/97; H01L 2225/06517; H01L 2924/1431

(57) ABSTRACT

In one example, an electronic device comprises a lower substrate, an upper substrate, internal interconnects, a bridge component, a lower encapsulant, and electronic components. The internal interconnects couple an upper side of the lower substrate to a lower side of the upper substrate. The bridge component comprises bridge first interconnects coupled to the upper substrate, second interconnects coupled to the lower substrate, and a bridge signal redistribution structure coupled to the bridge first interconnects and to the bridge second interconnects. The lower encapsulant encapsulates the internal components and the bridge component. The electronic components are coupled to the internal interconnects and the bridge redistribution structure via the upper side of the upper substrate. The bridge signal redistribution structure provides one or more signal paths between the first electronic component and the second electronic component. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A-2J show cross-sectional views of an example method for manufacturing the example electronic device of FIG. 1.

FIG. 3 shows a cross-sectional view of another example electronic device.

FIGS. 4A-4H show cross-sectional views of an example method for manufacturing the electronic device of FIG. 3.

### DESCRIPTION

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A may be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to an electrical coupling or a mechanical coupling.

In one example, a method of manufacturing an electronic device may comprise providing internal interconnects and a bridge assembly. The bridge assembly may comprise a bridge component coupled to a bridge die. The bridge component may comprise a bridge signal redistribution structure. The method may further comprise encapsulating the internal interconnects and the bridge assembly in a lower encapsulant, and removing the bridge die from the bridge assembly. Further, the method may comprises covering an upper side of the lower encapsulant with an upper substrate such that an upper substrate conductive structure is coupled to the internal interconnects and to the bridge signal redistribution structure. The method may also comprises coupling, via the upper substrate, first interconnects of a first electronic component to the signal redistribution conductive structure and second interconnects of the first electronic component to the internal interconnects, and coupling, via the upper substrate, first interconnects of a second electronic component to the signal redistribution conductive structure and second interconnects of the second electronic component to the internal interconnects.

In another example, an electronic device comprises a lower substrate, an upper substrate, internal interconnects, a bridge component, a lower encapsulant, and electronic components. The internal interconnects couple an upper side of the lower substrate to a lower side of the upper substrate. The bridge component comprises bridge first interconnects coupled to the upper substrate, second interconnects coupled to the lower substrate, and a bridge signal redistribution structure coupled to the bridge first interconnects and to the bridge second interconnects. The lower encapsulant encapsulates the internal components and the bridge component. The electronic components are coupled to the internal interconnects and the bridge redistribution structure via the upper side of the upper substrate. The bridge signal redistribution structure provides one or more signal paths between the first electronic component and the second electronic component.

Other examples are included in the present disclosure. Such examples may be found in the figures, in the claims, or in the description of the present disclosure.

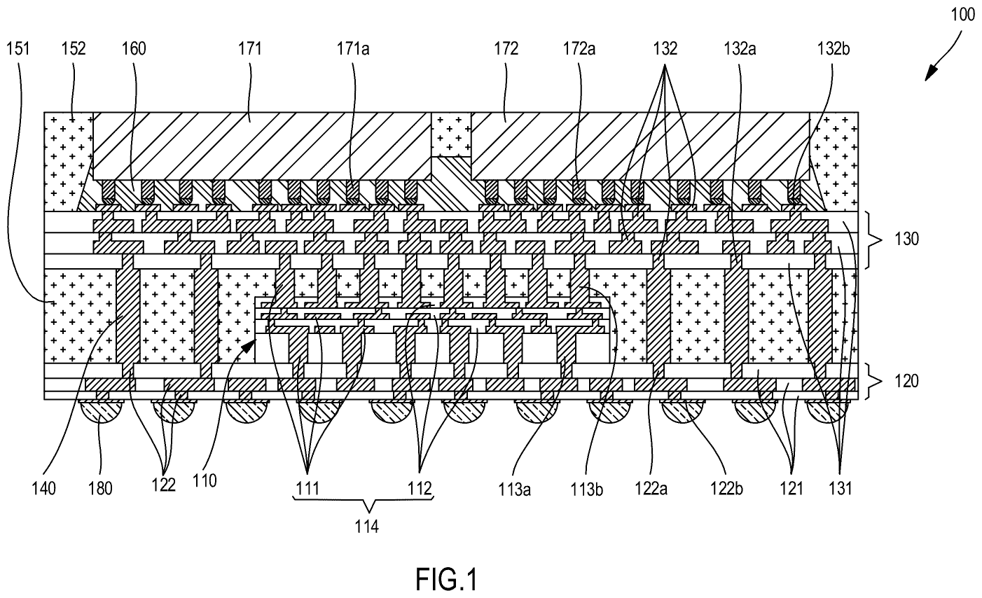

FIG. 1 shows a cross-sectional view of an example electronic device 100. In the example shown in FIG. 1, the electronic device 100 may comprise a bridge component 110, a lower substrate 120, an upper substrate 130, internal interconnects 140, a lower encapsulant 151, an upper encapsulant 152, a first electronic component 171, a second electronic component 172, and external interconnects 180. In some examples, the electronic device 100 may comprise an underfill 160.

The bridge component 110 may comprise bridge first interconnects 113a, bridge second interconnects 113b, and a bridge signal redistribution structure 114. The bridge signal redistribution structure 114 may comprise a signal redistribution conductive structure 111 and a signal redistribution dielectric structure 112. The signal redistribution conductive structure 111 may provide one or more signal paths through the signal redistribution dielectric structure 112 that couple (i) one or more of the bridge first interconnects 113a to one or more of the bridge second interconnects 113b, and/or (ii) one or more of the bridge first interconnects 113a to one or more of other bridge first interconnects 113a. In this manner, the bridge signal redistribution structure 114 via its signal redistribution conductive structure 111 may provide signal, ground, power, and/or other electrical paths between (i) the first electronic component 171 and the second electronic component 172, (ii) the first electronic component 171 and the lower substrate 120, and/or (iii) the second electronic component 172 and the lower substrate 120. In some examples, internal interconnects 140 may be employed for providing ground and/or power to first electronic component 171 and the second electronic component 172, and signal redistribution conductive structure 111 may be employed for signal paths to and from and between first electronic component 171 and second electronic component 172.

The lower substrate 120 may comprise a lower substrate dielectric structure 121 and a lower substrate conductive structure 122. The lower substrate conductive structure 122 may comprise upper terminals 122a and lower substrate lower terminals 122b. The upper substrate 130 may comprise an upper substrate dielectric structure 131 and an upper substrate conductive structure 132. The upper substrate 130 may comprise lower terminals 132a and upper terminals 132b.

The first electronic component 171 may comprise first interconnects 171a and second interconnects 171b. The second electronic component 172 may comprise first interconnects 172a and second interconnects 172b.

The bridge component 110, the lower substrate 120, the upper substrate 130, the internal interconnects 140, the lower encapsulant 151, the upper encapsulant 152, the underfill 160, and the external interconnects 180 may be referred to as an electronic package, such as a semiconductor package. The electronic package may protect the first electronic component 171 and the second electronic component 172 from external elements or environmental exposure and/or may provide electrical connection between the first electronic component 171 and the second electronic component 172 and/or between external devices/packages and the electronic components 171, 172.

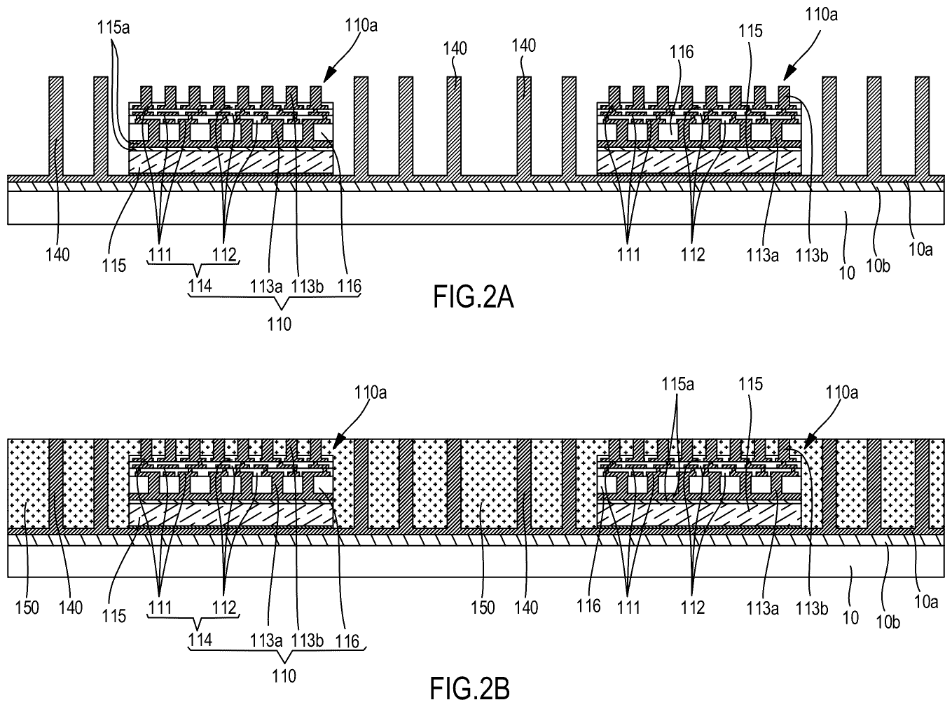

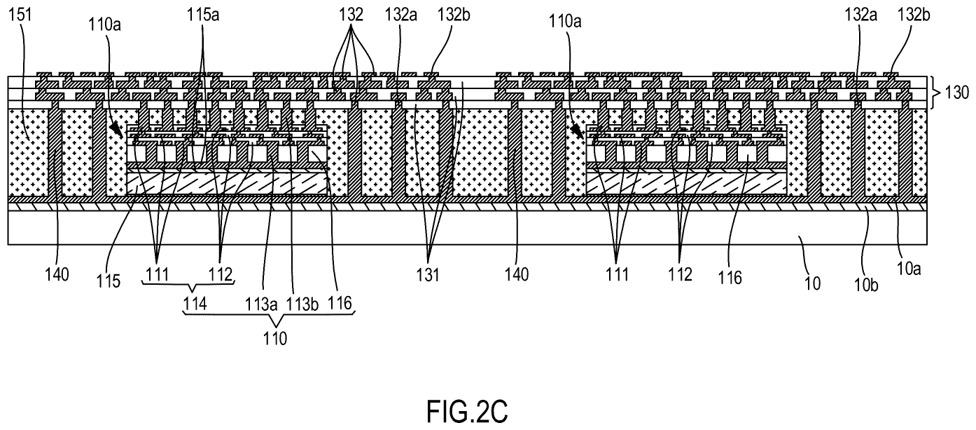

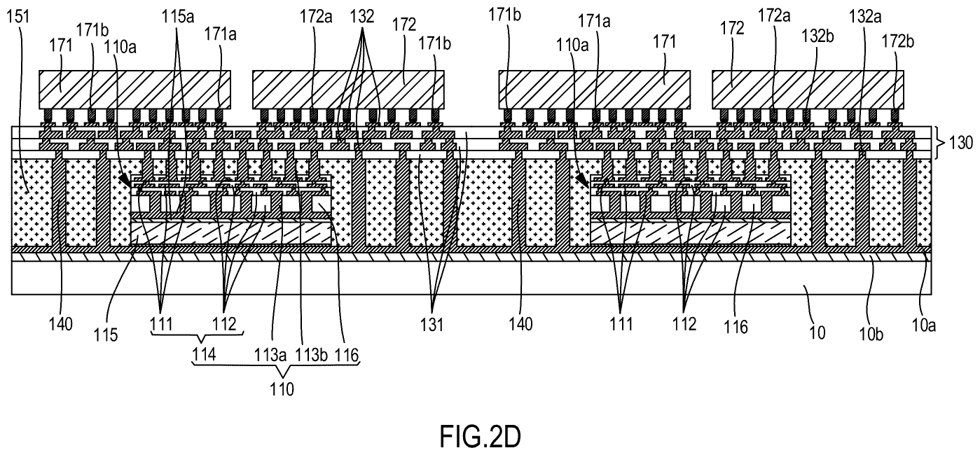

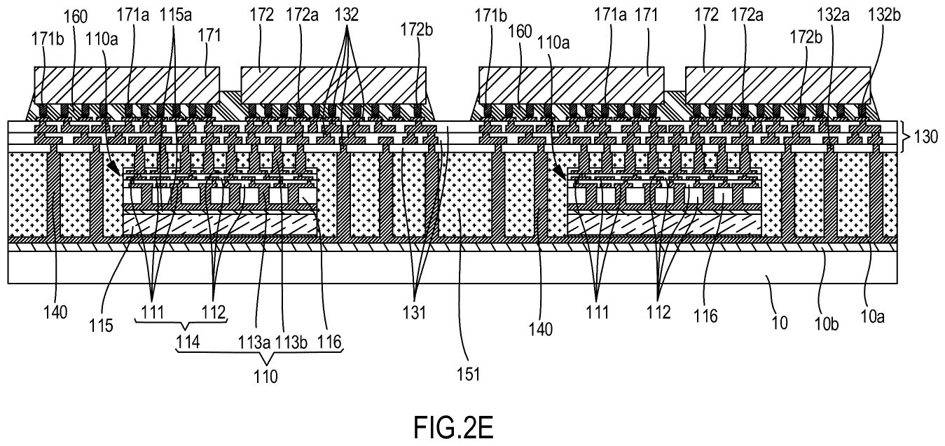

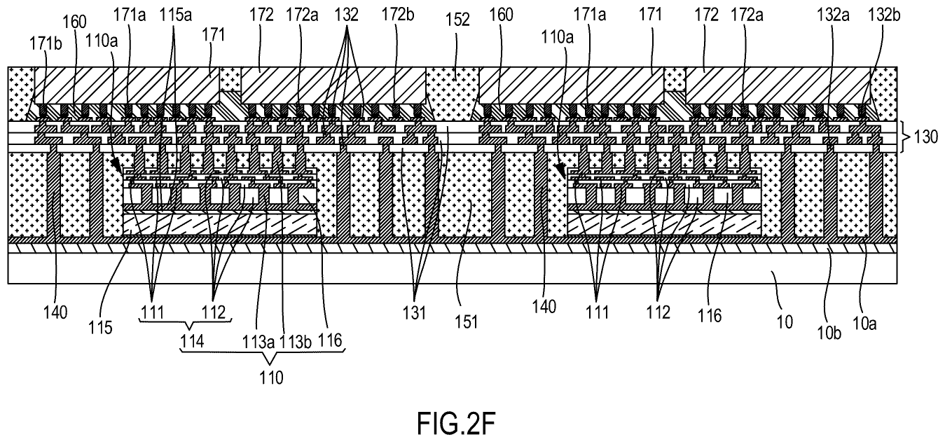

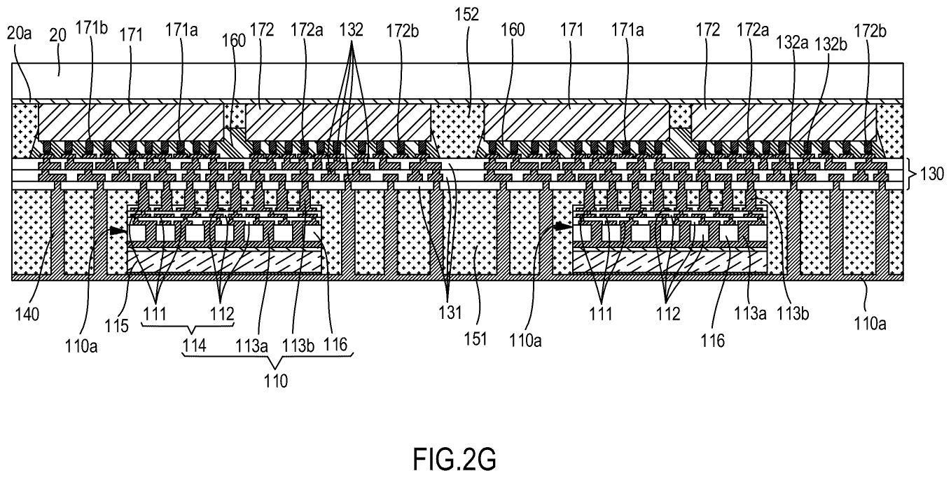

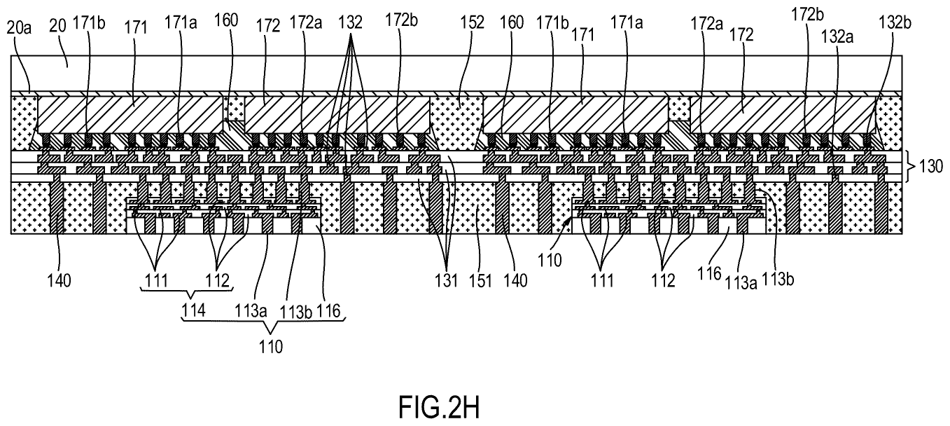

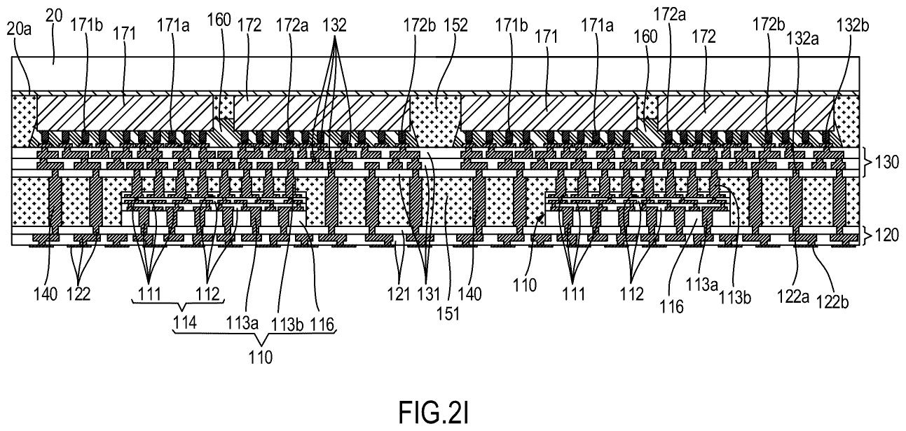

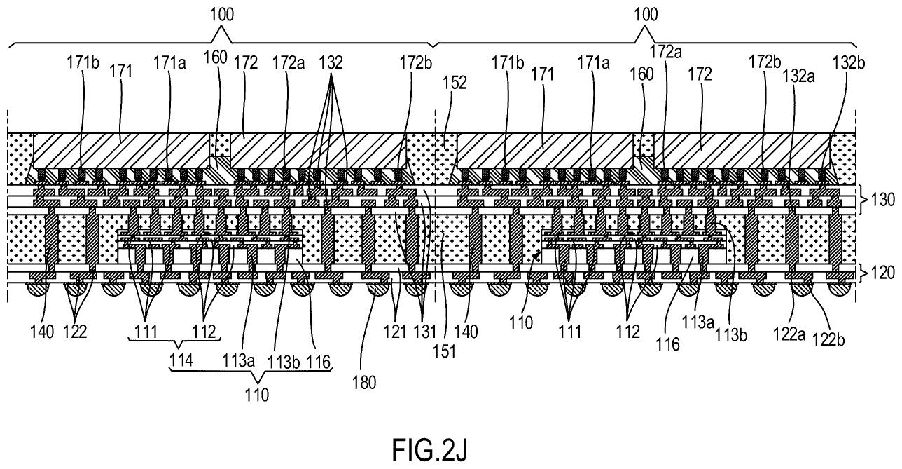

FIGS. 2A-2J show cross-sectional views of an example method for manufacturing the example electronic device 100 of FIG. 1.

FIG. 2A shows a cross-sectional view of the electronic device 100 at an early stage of manufacture. In the example shown in FIG. 2A, bridge assemblies 110a and the internal interconnects 140 may be provided on an upper side of a first carrier 10. Bridge assembly 110a may comprise a bridge base 115 and bridge component 110 over an upper side of the bridge base 115. In particular, the internal interconnects 140 may be spaced apart from sidewalls of the bridge component 110. Further, the internal interconnects 140 may be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD).

For example, a metal layer 10a may cover the upper side of the first carrier 10. The internal interconnects 140 may be provided on an upper side of the metal layer 10a. Here, the metal layer 10a may comprise or be referred to as a seed layer. In some examples, the internal interconnects 140 may be made of copper, gold, silver, palladium, or nickel. The internal interconnects 140 may comprise posts, pillars, vertical wires, bumps, or solder-coated-metallic-core-balls. As noted above, the internal interconnects 140 may be spaced apart from the sidewalls of the bridge component 110. The internal interconnects 40 may be further spaced apart from each other in a row or column direction.

The bridge component 110 and bridge base 115 may be provided on the upper side of the first carrier 10. In some examples, pick and place equipment may pick up a bridge assembly 110a comprising the bridge component 110 and the bridge base 115 and place the bridge assembly 110a on the upper side of the metal layer 10a that covers the first carrier 10. Moreover, the bridge assembly 110a may be adhered to the upper side of the metal layer 10a through an adhesive along a bottom side of the bridge base 115.

As shown, the bridge component 110 may be coupled to the top side of the bridge base 115. In particular, the bridge signal redistribution structure 114 may be provided on an upper side of the bridge base 115. In some examples, bridge base 15 can comprise a semiconductor material such as silicon. In some examples, the bridge base 115 can comprise a mold material, ceramic, or glass. The bridge first interconnects 113a may be coupled to the signal redistribution conductive structure 111 of the bridge signal redistribution structure 114 at a lower side of the bridge signal redistribution structure 114. Similarly, the bridge second interconnects 113b may be coupled to the signal redistribution conductive structure 111 of the bridge signal redistribution structure 114 at an upper side of the bridge signal redistribution structure 114. The bridge first interconnects 113a may pass through a bridge insulating body 116 to the upper side of the bridge base 115. Thus, sidewalls of the bridge first interconnects 113a may contact the bridge insulating body 116. The bridge insulating body 116 may be a part of signal redistribution dielectric structure 112. The bridge second interconnects 113b may protrude above an upper side of the bridge signal redistribution structure 114.

The bridge base 115 may comprise an upper metal 115a covering the upper side of the bridge base 115. Via the upper metal 115a, the bridge first interconnects 113a may be coupled to the upper side of bridge base 115. As such, the upper metal 115a may prevent metal of the bridge first interconnects 113a from diffusing toward bridge base 115. In some examples, the upper metal 115a may comprise a multilayer thin film made of titanium and copper.

The bridge first interconnects 113a may be provided by providing a mask pattern on the upper side of upper metal 115a and plating the bridge first interconnects 113a using upper metal 115a as a seed layer. For example, the mask pattern may be provided by a photoresist. The mask pattern may then be removed after the bridge first interconnects 113a are provided. The bridge first interconnects 113a may be provided on the upper side of bridge base 115 such that the bridge first interconnects 113a are spaced apart from each other in the row or column direction. The bridge first interconnects 113a may comprise or be referred to as pads, bumps, pillars, posts, or vias. In some examples, the bridge first interconnects 113a may comprise copper, gold, silver, or nickel. In some examples, the bridge first interconnects 113a may be provided by electroless plating, electrolytic plating, sputtering, PVD, CVD, MOCVD, ALD, LPCVD, or PECVD.

The bridge insulating body 116 may cover an upper side of the bridge base 115. The bridge first interconnects 113a may pass between the upper side and lower side of the bridge insulating body 116. The bridge insulating body 116 may be provided to cover the upper side of the bridge base 115 and the upper sides of the bridge first interconnects 113a. The upper sides of the bridge first interconnects 113a may then be exposed through a planarization process. In some examples, the bridge insulating body 116 may comprise or be referred to as a dielectric layer, coreless layer, or filler-free layer of the bridge signal redistribution structure 114. For example, the bridge insulating body 116 may comprise an electrical insulating material such as polyimide (PI), benzocyclobutene (BCB), polybenzoxazole (PBO), resin, a molding material, an epoxy, an acrylate polymer, or Ajinomoto Buildup Film (ABF). In some examples, the bridge insulating body 116 may be provided by spin coating, spray coating, dip coating, rod coating, or any other suitable deposition method. In some examples, the thickness of bridge insulating body 116 may be similar to the thickness of the bridge first interconnects 113a. In some examples, the bridge insulating body 116 may be provided before the bridge first interconnects 113a, and the bridge first interconnects 113a may then be provided to pass through the bridge insulating body 116.

One or more dielectric layers of the signal redistribution dielectric structure 112 may be provided to cover the upper side of the bridge insulating body 116 and the upper sides of the bridge first interconnects 113a. The one or more dielectric layers of the signal redistribution dielectric structure 112 may be provided to cover the upper sides of bridge first interconnects 113a and the upper side of the bridge insulating body 116. Openings may then be provided to expose the upper sides of the bridge first interconnects 113a. For example, the openings may be provided by forming a mask pattern on the upper side of the signal redistribution dielectric structure 112 and then removing exposed portions of the signal redistribution dielectric structure 112 through etching. In some examples, the openings may be referred to as or comprise apertures or holes. In some examples, the one or more dielectric layers of the signal redistribution dielectric structure 112 may be provided by a similar material and method of providing the bridge insulating body 116.

One or more conductive layers of the signal redistribution conductive structure 111 may be over one or more dielectric layers of the signal redistribution dielectric structure 112 and over the bridge first interconnects 113a. The one or more conductive layers of the signal redistribution conductive structure 111 may be provided with multiple patterns and electrically coupled to the bridge first interconnects 113a. In some examples, the one or more conductive layers of the signal redistribution conductive structure 111 may comprise or be referred to as traces, pads, vias, redistribution layers (RDLs), wiring pattern, or circuit pattern. In some examples, the one or more conductive layers of the signal redistribution conductive structure 111 may comprise copper, gold, silver, or nickel.

One or more dielectric layers of the signal redistribution dielectric structure 112 may be provided to cover one or more conductive layers of the signal redistribution conductive structure 111 and one or more dielectric layers of the signal redistribution dielectric structure 112. One or more conductive layers of the signal redistribution conductive structure 111 may be provided on the upper side of one or more conductive layers of the signal redistribution conductive structure 111 and on the upper side of one or more dielectric layers of the signal redistribution dielectric structure 112. One of more dielectric layers of the signal redistribution dielectric structure 112 and one or more conductive layers of the signal redistribution conductive structure 111 may be alternately sequentially provided. The bridge insulating body 116 may be between one of the dielectric layers of the signal redistribution dielectric structure 112 and bridge base 115.

The bridge second interconnects 113b may be provided on an upper side of the bridge signal redistribution structure 114. In particular, the bridge second interconnects 113b may protrude above an upper side of the uppermost conductive layer of the signal redistribution conductive structure 111 and above an upper side of the uppermost dielectric layer of the signal redistribution dielectric structure 112. The bridge second interconnects 113b may be provided by materials and methods similar to those used to provide the bridge first interconnects 113a.

In some examples, the signal redistribution dielectric structure 112 may comprises multiple (e.g., 2, 3, 4, etc.) dielectric layers and the signal redistribution conductive structure 111 may comprise multiple (e.g., 2, 3, 4, etc.) conductive layers. One or more layers or elements of the signal redistribution conductive structure 111 may be interleaved with one or more layers or elements of the signal redistribution dielectric structure 112. In some examples, the bridge first interconnects 113a and the bridge second interconnects 113b may be parts of or integral with the signal redistribution conductive structure 111. One or more layers of elements of the signal redistribution conductive structure 111 located on the lowermost side of signal redistribution conductive structure 111 may comprise or be referred to as the bridge first interconnects 113a. Similarly, one or more layers or elements of the signal redistribution conductive structure 111 located on the uppermost side of the signal redistribution conductive structure 111 may comprise or be referred to as the bridge second interconnects 113b. In some examples, the thickness of the bridge second interconnects 113b and/or the bridge first interconnects 113a may be greater than the thickness of the conductive layers of the signal redistribution conductive structure 111.

After the signal redistribution dielectric structure 112 and the signal redistribution conductive structure 111 of the bridge signal redistribution structure 114 are provided on the upper side of the bridge base 115, a singulation process may be performed wherein the bridge component 110 and bridge base 115 are separated into individual bridge assemblies 110a by sawing the bridge base 115 and bridge signal redistribution structure 114. In some examples, during the singulation process, a diamond blade or laser beam may be used.

The first carrier 10 may comprise a substantially planar plate. In some examples, the first carrier 10 may comprise or be referred to as a plate, a board, a wafer, a panel, or a strip. For example, the first carrier 10 may be made of steel, stainless steel, aluminum, copper, ceramic, glass, or wafer. In some examples, the thickness of the first carrier 10 may range from approximately 300 μm to approximately 2000 μm, and the width or diameter of the first carrier 10 may range from approximately 100 millimeters (mm) to approximately 300 mm. In some examples, the width or diameter of first carrier 10 can be larger than 300 mm (e.g., 600 mm). The first carrier 10 may serve to enable multiple components to be handled as one in the process of providing the bridge component 110, the upper substrate 130, the internal interconnects 140, the lower encapsulant 151, the upper encapsulant 152, the underfill 160, the first electronic component 171, and the second electronic component 172.

The first carrier 10 may comprise a temporary bond layer 10b provided on the surface of the first carrier 10. The metal layer 10a may be provided on the surface of temporary bond layer 10b of the first carrier 10. The temporary bond layer 10b may be provided on the surface of the first carrier 10 by a coating method such as spin coating, doctor blade coating, casting, painting, spray coating, slot die coating, curtain coating, slide coating, or knife over edge coating; a printing method such as screen printing, pad printing, gravure printing, flexography printing, or offset printing, or an inkjet printing method; an intermediate technology between coating and printing; or may be provided by direct attachment of a bonding film or bonding tape. In some examples, the temporary bond layer 10b may comprise or be referred to as a temporary bonding film, a temporary bonding tape or a temporary adhesive coating. For example, the temporary bonding layer may be a heat release tape (film) or an optical release tape (film), the adhesive strength is weakened or removed by heat or light. The temporary bond layer 10b may allow the first carrier 10 to be separated from the lower encapsulant 151 (FIG. 2B) before the lower substrate 120 (FIG. 2I) is provided, and will later be described.

FIG. 2B shows a cross-sectional view of the electronic device 100 at a later stage of manufacture. In the example shown in FIG. 2B, the lower encapsulant 151 may be provided to cover the bridge assembly 110a and the internal interconnects 140. In some examples, the lower encapsulant 151 may comprise or be referred to as a body or a molding. For example, the lower encapsulant 151 may comprise an epoxy mold compound, a resin, a filler-reinforced polymer, a B-stage pressed film, or a gel. For example, the lower encapsulant 151 may be provided by compression molding, transfer molding, liquid body molding, vacuum lamination, paste printing, or film assist molding.

An upper portion of the lower encapsulant 151 may be removed to expose the upper side of bridge assembly 110a and the upper sides of the internal interconnects 140. The lower encapsulant 151 may be in contact with the sidewall of the bridge component 110, the sidewall of the bridge base 115, and respective sidewalls of internal interconnects 140. The lower encapsulant 151 may also contact respective sidewalls of the bridge second interconnects 113b. In some examples, the lower encapsulant 151 may have an upper portion removed by grinding. In some examples, when the upper portion of the lower encapsulant 151 is removed, upper portions of the internal interconnects 140 and the upper portions of the bridge second interconnects 113b may also be removed. In some examples, the upper sides of the bridge second interconnects 113b, the upper sides of internal interconnects 140, and the upper side of the lower encapsulant 151 may be coplanar. The thickness (i.e., height) of the lower encapsulant 151, the height of the internal interconnects 140, and the height of bridge assembly 110a may be equal or approximately equal.

FIG. 2C shows a cross-sectional view of the electronic device 100 at a later stage of manufacture. In the example shown in FIG. 2C, the upper substrate 130 may be provided on the upper side of the lower encapsulant 151, the upper sides of the bridge second interconnects 113b, and the upper sides of the internal interconnects 140. The upper substrate 130 may comprise an upper substrate dielectric structure 131 and an upper substrate conductive structure 132.

After one or more dielectric layers of the upper substrate dielectric structure 131 cover the upper side of the lower encapsulant 151, the upper sides of the bridge second interconnects 113b, and the upper sides of the internal interconnects 140, apertures exposing the upper sides of the bridge second interconnects 113b and the upper sides of the internal interconnects 140 may be provided. The one or more dielectric layers of the upper substrate dielectric structure 131 may comprise or be referred to as dielectric layers, coreless layers, or a filler-free layers. In some examples, the one or more dielectric layers of the upper substrate dielectric structure 131 may comprise an electrically insulating material such as a polymer, polyimide (PI), benzocyclobutene (BCB), polybenzoxazole (PBO), bismaleimide triazine (BT), a molding material, a phenolic resin, an epoxy, silicone, or an acrylate polymer. In some examples, the one or more dielectric layers of the upper substrate dielectric structure 131 may be provided by spin coating, spray coating, dip coating, or rod coating. After a mask pattern is provided on the upper side of the upper substrate dielectric structure 131, exposed portions of the upper substrate dielectric structure 131 may be removed through etching to expose the upper sides of the bridge second interconnects 113b and the upper sides of the internal interconnects 140.

One or more conductive layers of the upper substrate conductive structure 132 may be patterned. The one or more patterned conductive layers of the upper substrate conductive structure 132 may contact and/or be coupled to the upper sides of the bridge second interconnects 113b and/or the upper sides of the internal interconnects 140. The one or more conductive layers of the upper substrate conductive structure 132 may define signal distribution elements of the upper substrate 130. The one or more conductive layers of the upper substrate conductive structure 132 may comprise or be referred to traces, pads, vias, RDLs, wiring patterns, or circuit patterns. In some examples, the one or more conductive layers of the upper substrate conductive structure 132 may comprise silver, copper, gold, silver, or nickel. For example, the one or more conductive layers of the upper substrate conductive structure 132 may be provided by electroless plating, electrolytic plating, sputtering, PVD, CVD, MOCVD, ALD, LPCVD, or PECVD.

In accordance with various examples, the upper substrate dielectric structure 131 and/or the upper substrate conductive structure 132 may comprise any quantity of layers. As such, the upper substrate 130 may comprise or be referred to as a redistribution layer (“RDL”) substrate or an interposer. When the upper substrate dielectric structure 131 and/or the upper substrate conductive structure 132 comprise multiple layers, such layers of the upper substrate 130 may be alternately sequentially provided. In particular, one or more conductive layers or elements of the upper substrate conductive structure 132 may be interleaved with one or more dielectric layers or elements of the upper substrate dielectric structure 131.

The upper terminals 132b of the upper substrate 130 may be provide by one or more upper conductive layers or elements of the upper substrate conductive structure 132. The lower terminals 132a of the upper substrate 130 may be provide by one or more lower conductive layers or elements of the upper substrate conductive structure 132. Respective ones of the lower terminals 132a may contact the upper sides of the bridge second interconnects 113b and/or the upper side of internal interconnects 140. The upper terminals 132b may be provided along the upper side of the upper substrate 130 and may be spaced apart from each other in a row and/or column direction. The lower terminals 132a may be provided along the lower side of the upper substrate 130 and may be spaced apart from each other in a row and/or column direction. The lower terminals 132a and the upper terminals 132b may comprise or be referred to as pads, lands, UBMs, or studs.

In some examples, the upper substrate 130 may comprise a RDL substrate. RDL substrates may comprise one or more conductive redistribution layers and one or more dielectric layers and (a) may be formed layer by layer over an electronic component to which the RDL substrate is to be coupled, or (b) may be formed layer by layer over a carrier that may be entirely removed or at least partially removed after the electronic component and the RDL substrate are coupled together. RDL substrates may be manufactured layer by layer as a wafer-level substrate on a round wafer in a wafer-level process, and/or as a panel-level substrate on a rectangular or square panel carrier in a panel-level process. RDL substrates may be formed in an additive buildup process and may include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns may be formed using a plating process such as, for example, an electroplating process or an electroless plating process. The conductive patterns may comprise a conductive material such as, for example, copper or other plateable metal. The locations of the conductive patterns may be made using a photo-patterning process such as, for example, a photolithography process and a photoresist material to form a photolithographic mask. The dielectric layers of the RDL substrate may be patterned with a photo-patterning process, and may include a photolithographic mask through where light is exposed to photo-pattern desired features such as vias in the dielectric layers. The dielectric layers may be made from photo-definable organic dielectric materials such as, for example, PI, BCB, or PBO. Such dielectric materials may be spun-on or otherwise coated in liquid form, rather than attached as a pre-formed film. To permit proper formation of desired photo-defined features, such photo-definable dielectric materials may omit structural reinforcers or may be filler-free, without strands, weaves, or other particles that could interfere with the light from the photo-patterning process. In some examples, such filler-free characteristics of filler-free dielectric materials may permit a reduction of the thickness of the resulting dielectric layer. Although the photo-definable dielectric materials described above may be organic materials, in some examples the dielectric materials of the RDL substrates may comprise one or more inorganic dielectric layers. Some examples of inorganic dielectric layer(s) may comprise silicon nitride (Si₃N₄), silicon oxide (SiO₂), and/or silicon oxynitride (SiON). The inorganic dielectric layer(s) may be formed by growing the inorganic dielectric layers using an oxidation or nitridization process instead using photo-defined organic dielectric materials. Such inorganic dielectric layers may be filler-fee, without strands, weaves, or other dissimilar inorganic particles. In some examples, the RDL substrates may omit a permanent core structure or carrier such as, for example, a dielectric material comprising bismaleimide triazine (BT) or FR4 and these types of RDL substrates may comprise or be referred to as a coreless substrate. Other substrates in this disclosure may also comprise an RDL substrate.

In some examples, the upper substrate 130 may be a pre-formed substrate. The pre-formed substrate may be manufactured prior to attachment to an electronic component and may comprise dielectric layers between respective conductive layers. The conductive layers may comprise copper and may be formed using an electroplating process. The dielectric layers may be relatively thicker non-photo-definable layers and may be attached as a pre-formed film rather than as a liquid and may include a resin with fillers such as strands, weaves, and/or other inorganic particles for rigidity and/or structural support. Since the dielectric layers may be non-photo-definable, features such as vias or openings may be formed by using a drill or laser. In some examples, the dielectric layers may comprise a prepreg material or Ajinomoto Buildup Film (ABF). The pre-formed substrate may include a permanent core structure or carrier such as, for example, a dielectric material comprising bismaleimide triazine (BT) or FR4, and dielectric and conductive layers may be formed on the permanent core structure. In other examples, the pre-formed substrate may be a coreless substrate and omits the permanent core structure, and the dielectric and conductive layers may be formed on a sacrificial carrier and is removed after formation of the dielectric and conductive layers and before attachment to the electronic device. The pre-formed substrate may be referred to as a printed circuit board (PCB) or a laminate substrate. Such pre-formed substrate may be formed through a semi-additive or modified-semi-additive process. Other substrates in this disclosure may also comprise a pre-formed substrate.

FIG. 2D shows a cross-sectional view of the electronic device 100 at a later stage of manufacture. In the example shown in FIG. 2D, the first electronic component 171 and the second electronic component 172 may be provided over the upper substrate 130. The first electronic component 171 and the second electronic component 172 may contact and/or be electrically coupled to the upper terminals 132b of the upper substrate 130. In some examples, the lower side of the first electronic component 171 and the lower side of the second electronic component 172 may comprise or be referred to as the active side of the respective component. The upper side of the first electronic component 171 and the upper side of the second electronic component 172 may comprise or be referred to as the inactive side of the respective component. The first electronic component 171 may comprise first interconnects 171a and second interconnects 171b on the lower side of the first electronic component 171. The first interconnects 171a and the second interconnects 171b of the first electronic component 171 may be spaced apart from each other in the row and/or column direction. Similarly, the second electronic component 172 may comprise first interconnects 172a and second interconnect 172b on the lower side of the second electronic component 172. The first interconnects 172a and the second interconnects 172b of the second electronic component 172 may be spaced apart from each other in the row and/or column direction. Each interconnect 171a, 171b, 172a, and 172b may comprise or be referred to as a bump, pad, or pillar. Each interconnect 171a, 171b, 172a, 172b may be an input/output terminal of the respective electronic component 171, 172. In some examples, each interconnect 171a, 171b, 172a, 172b may be provided by electrolytic plating, electroless plating, sputtering, PVD, CVD, MOCVD, ALD, LPCVD, or PECVD. For example, after providing a photoresist pattern that exposes bond pads of the electronic components 171, 172, the interconnects 171a, 171b, 172a, 172b may be provided to be in contact with exposed bond pads. In some examples, the thickness (i.e., height) of the interconnects 171a, 171b, 172a, and 172b may range from approximately 1 μm to approximately 100 μm, and the width and/or pitch of interconnects 171a, 171b, 172a, 172b may range from approximately 5 μm to approximately 200 μm. In some examples, the interconnects 171a, 172a which couple the respective electronic component 171, 172 to the bridge component 110 are spaced closer together, at a finer pitch, or at a higher density than the interconnects 171b, 172b. As such, the interconnects 171a, 172a may be referred to as high-density interconnects and the interconnects 171b, 172b may be referred to as low-density interconnects.

In some examples, pick and place equipment may pick up the electronic components 171, 172 and place the electronic components 171, 172 on the upper side of the upper substrate 130. Such placement may locate interconnects 171a, 171b, 172a, 172b of the electronic components 171, 172 in contact with upper sides of the upper terminals 132b. Subsequently, the interconnects 171a, 171b, 172a, 172b of the electronic components 171, 172 may be bonded to the upper terminals 132b through a reflow or thermocompression bonding process. In some examples, hybrid bonding may be employed to couple the electronic components 171, 172 to the upper terminals 132b. In some examples, the electronic components 171, 172 may comprise or be referred to as dies, chips, or packages. In some examples, one of electronic component 171 or electronic component 172 may comprise a logic die or logic device and the other electronic component 171 and electronic component 172 may comprise a memory package (e.g., one or more stacked memory die or memory devices). The electronic components 171, 172 may be electrically coupled to the bridge component 110 and the internal interconnects 140 through the upper substrate conductive structure 132 of the upper substrate 130. The electronic components 171, 72 may be electrically coupled to each other through the upper substrate 130 and the bridge component 110. While two electronic components 171, 172 are shown, the electronic device 100 in some examples may comprise a greater quantity of electronic components.

The electronic components 171, 172 are shown as having a face-down or flip-chip configuration where component terminals located on the lower side are coupled to the upper substrate 130 via interconnects 171a, 171b, 172a, 172b between the lower side of the electronic components 171, 172 and the upper side of the upper substrate 130. However, in some examples, the electronic components 171, 172 may be in a face-up or wire bonding configuration where component terminals are located on the upper side. In such examples, the upper side of electronic component 171, 172 may comprise or be referred to as the active side, and the lower side of electronic component 171, 172 may comprise or be referred to as the inactive side. The inactive side of the electronic components 171 and 172 may be adhered of the upper substrate 130. The electronic components 171 and 172 may have component terminals located on the upper surfaces of the active sides. The electronic components 171, 172 may comprise or be referred to as face-up or wire-bonded components. The component terminals of the face-up electronic components 171, 172 may be electrically coupled to the upper terminals 132b of the upper substrate 130 through wire bonds or conductive wires. The conductive wires may comprise gold wires, copper wires, or aluminum wires. In such examples, the component terminals of face-up electronic components 171, 172 may be bonded to the upper terminals 132b of the upper substrate 130 through wire bonding equipment. In some examples, the total thickness of each electronic component 171, 172 may range from approximately 50 μm to approximately 1000 μm, and the area of each electronic component 171, 172 may range from approximately 0.5 mm×0.5 mm to approximately 70 mm×70 mm.

FIG. 2E shows a cross-sectional view of the electronic device 100 at a later stage of manufacture. In the example shown in FIG. 2E, the underfill 160 may be positioned between each electronic component 171, 172 and the upper side of the upper substrate 130. The underfill 160 may contact the lower side of each electronic components 171, 172 and the upper side of the upper substrate 130. The underfill 160 may contact the interconnects 171a, 171b, 172a, 172b of the electronic components 171, 172. The underfill 160 may comprise or be referred to as a dielectric layer or non-conductive paste and may be devoid of inorganic fillers. In some examples, the underfill 160 may comprise or be referred to as a capillary underfill (CUF), a nonconductive paste (NCP), a nonconductive film (NCF), an anisotropic conductive film (ACF), or an anisotropic conductive paste (ACP). In some examples, when the underfill 160 comprises a molded underfill (MUF), the underfill 160 may be considered part of or be provided by the upper encapsulant 152. In some examples, the underfill 160 may be inserted between each electronic component 171, 172 and the upper substrate 130. In some examples, after the underfill 160 is provided to over the upper side of the upper substrate 130, the interconnects 171a, 171b, 172a, 172b of the electronic components 171, 172 may penetrate the underfill 160 couple to the upper terminals 132b of the upper substrate 130. The underfill 160 may protect against physical and thermal shocks and/or prevent or reduce occurrence of the electronic components 171, 172 separating from the upper substrate 130.

FIG. 2F shows a cross-sectional view of electronic device 100 at a later stage of manufacture. In the example shown in FIG. 2F, the upper encapsulant 152 may be provided to cover the upper side of the upper substrate 130, the underfill 160, and the electronic components 171, 172. The upper encapsulant 152 may contact the upper side of the upper substrate 130, the sidewalls of the electronic components 171, 172, and the sidewalls of the underfill 160.

The upper encapsulant 152 may have corresponding elements, features, materials, or manufacturing methods similar to those of the lower encapsulant 151. In some examples, the upper encapsulant 152 may expose the upper side of the electronic components 171, 172. The thickness of the upper encapsulant 152 and the height of each electronic component 171, 172 may be similar. In some examples, the thickness of the upper encapsulant 152 may range from approximately 50 μm to approximately 1800 μm. In some examples, a lid may be provided on and coupled to upper sides of electronic components 171, 172 exposed at the upper side of the upper encapsulant 152. A thermal interface material (TIM) and a back side metal (BSM) may be interposed between the lid and the electronic components 171, 172 to facilitate heat transfer and coupling.

FIG. 2G shows a cross-sectional view of the electronic device 100 at a later stage of manufacture. In the example shown in FIG. 2G, a second carrier 20 is provided and coupled to the upper side of the electronic component 171, 172 and the upper side of upper encapsulant 152. After such coupling, the first carrier 10 may be removed from the lower side of the lower encapsulant 151, the lower side of the bridge assembly 110a, and the lower sides of the internal interconnects 140.

The second carrier 20 may cover the upper side of each electronic component 171, 172 and the upper side of the upper encapsulant 152. The lower side of the second carrier 20 may comprise a temporary bond layer 20a. The temporary bond layer 20a may contact and affix the second carrier 20 to the upper side of each electronic component 171, 172 and the upper side of upper encapsulant 152. The temporary bond layer 20a may have corresponding elements, features, materials, or manufacturing methods similar to those of the temporary bond layer 10b of the first carrier 10. When the manufacture of the electronic device 100 is completed, the temporary bond layer 20a may permit separating the second carrier 20 from the electronic component 171, 172 and the upper encapsulant 152.

FIG. 2H shows a cross-sectional view of the electronic device 100 at a later stage of manufacture. In the example shown in FIG. 2H, a lower portion of bridge assembly 110a, a lower portion of internal interconnects 140, and a lower portion of the lower encapsulant 151 may be removed. For example, after the first carrier 10 is removed, the lower side of the lower encapsulant 151, the lower side of the internal interconnects 140, and the lower side of the bridge assembly 110a may be partially removed through grinding and/or etching. The lower side of the internal interconnects 140 and the lower side of the bridge first interconnects 113a of the bridge component 110 may be exposed at the lower side of the lower encapsulant 151. The lower side of bridge signal redistribution structure 114 may be exposed at the lower side of the lower encapsulant 151. As shown, the grinding and/or etching may remove the bridge base 115, thus leaving the bridge component 110. The bridge signal redistribution structure 114 via its signal redistribution conductive structure 111 may provide signal transmission between the bridge first interconnects 113a and the bridge second interconnects 113b. The heights of the bridge component 110, the lower encapsulant 151, and the internal interconnects 140 may be equal or approximately equal after such grinding and/or etching.

FIG. 2I shows a cross-sectional view of the electronic device 100 at a later stage of manufacture. In the example shown in FIG. 2I, the lower substrate 120 may cover the lower side of the lower encapsulant 151, the lower sides of internal interconnects 140, and the lower side of the bridge component 110.

The lower substrate 120 may comprise a lower substrate dielectric structure 121 and a lower substrate conductive structure 122. After one or more dielectric layers of the lower substrate dielectric structure 121 cover the lower side of the lower encapsulant 151, the lower side of the internal interconnects 140, and the lower side of the bridge component 110, apertures exposing the lower sides of internal interconnects 140 and the lower sides of the bridge first interconnects 113a may be provided. One or more conductive layers of the lower substrate conductive structure 122 may be provided to contact the lower sides of bridge first interconnects 113a and the lower sides of the internal interconnects 140.

The lower substrate 120 may have corresponding elements, features, materials, or manufacturing methods similar to those of the upper substrate 130. For example, when lower substrate conductive structure 122 is multilayered, the lower terminals 122b of the lower substrate 120 may be provided by one or more lower conductive layers of the lower substrate conductive structure 122. Similarly, the upper terminals 122a of the lower substrate 120 may be provided by one or more upper conductive layers of the lower substrate conductive structure 122. Respective ones of the upper terminals 122a may contact the lower sides of the bridge first interconnects 113a and/or the lower sides of the internal interconnects 140. The upper terminals 122a may be provided along the upper side of the lower substrate 120 and may be spaced apart from each other in a row and/or column direction. The lower terminals 122b may be provided along the lower side of the lower substrate 120 and may be spaced apart from each other in a row and/or column direction.

FIG. 2J shows a cross-sectional view of the electronic device 100 at a later stage of manufacture. In the example shown in FIG. 2J, the external interconnects 180 may be provided along the lower side of the lower substrate 120, and the electronic device 100 may undergo a singulation process.

The external interconnects 180 may contact and/or be coupled to the lower terminals 122b of the lower substrate 120. In some examples, the external interconnects 180 may comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, the external interconnects 180 may be provided by using a ball drop method to form a conductive material including solder on the lower terminals 122b and then performing a reflow process. The external interconnects 180 may comprise or be referred to as conductive balls such as solder balls, conductive pillars such as copper pillars, or conductive posts each having a solder cap provided on a copper pillar. In some examples, the external interconnects 180 may be ball grid arrays or land grid arrays along the lower side of the lower substrate 120. In some examples, the sizes of the external interconnects 180 may range from approximately 0.5 μm to approximately 1000 μm.

The external interconnects 180 may be electrically coupled to the electronic components 171, 172 through the lower substrate 120, the internal interconnects 140, and the upper substrate 130, and/or may be electrically coupled to electronic components 171, 172 through the lower substrate 120, the bridge component 110, and the upper substrate 130. After the external interconnects 180 are provided, the electronic device 100 may undergo a singulation process to be separated into individual electronic devices 100 by sawing the lower encapsulant 151, the upper encapsulant 152, the upper substrate 130, and lower substrate 120. In some examples, during the singulation process, a diamond blade or laser beam may be used. The second carrier 20 attached to the upper side of the discrete electronic device 100 may also be removed. In some examples, the external interconnects 180 may comprise or be referred to as external input/output terminals of the discrete electronic device 100.

The completed electronic device 100 may comprise the bridge component 110, the lower substrate 120, the upper substrate 130, the internal interconnects 140, the lower encapsulant 151, the upper encapsulant 152, the electronic components 171, 172, and the external interconnects 180. In some examples, the electronic device 100 may also comprise the underfill 160.

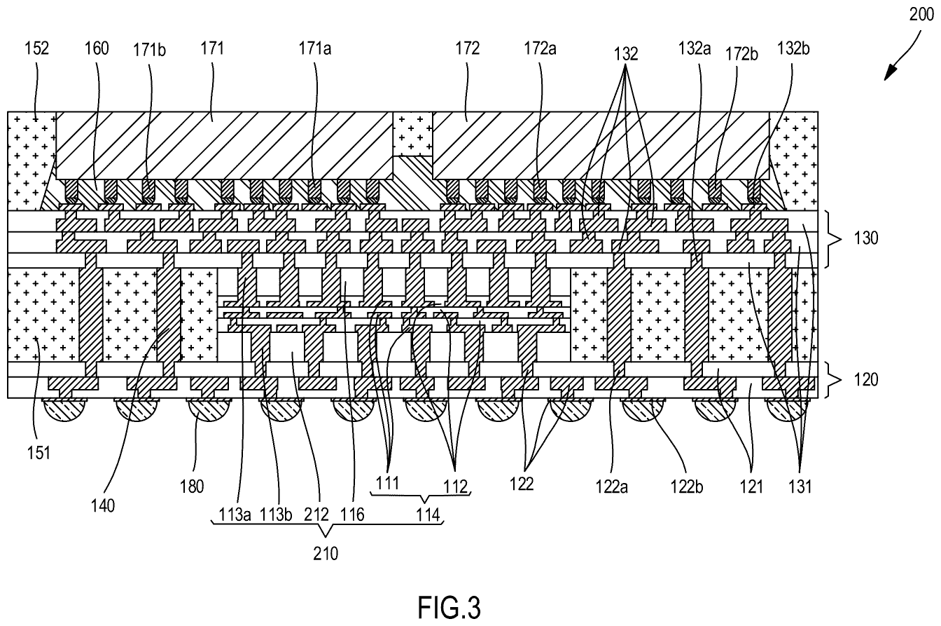

FIG. 3 shows a cross-sectional view of an example electronic device 200. In the example shown in FIG. 3, the electronic device 200 may comprise the bridge component 210, the lower substrate 120, the upper substrate 130, the internal interconnects 140, the lower encapsulant 151, the upper encapsulant 152, the electronic components 171, 172, and the external interconnects 180. In some examples, the electronic device 200 may also comprise the underfill 160.

The electronic device 200 of FIG. 1 may be implemented in a similar manner as the electronic device 100 of FIG. 3. For example, the electronic device 200 may be similar to the electronic device 100 in terms of the lower substrate 120, the upper substrate 130, the internal interconnects 140, the lower encapsulant 151, the upper encapsulant 152, the electronic components 171, 172, the external interconnects 180, and the underfill 160. However, the electronic device 200 may comprise a bridge component 210 instead of the bridge component 110 of the electronic device 100. Similar to the bridge component 110 of the electronic device 100, the bridge component 210 of the electronic device 200 may comprise a bridge signal redistribution structure 114, bridge first interconnects 113a, bridge second interconnects 113b, and bridge insulating body 116. However, the bridge component 210 of the electronic device 200 comprises a lower (or second) bridge insulating body 212. In electronic device 200, bridge insulating body 116 may be oriented away from and/or distal to lower substrate 120, and lower bridge insulating body 212 may be oriented toward and/or proximate lower substrate 120.

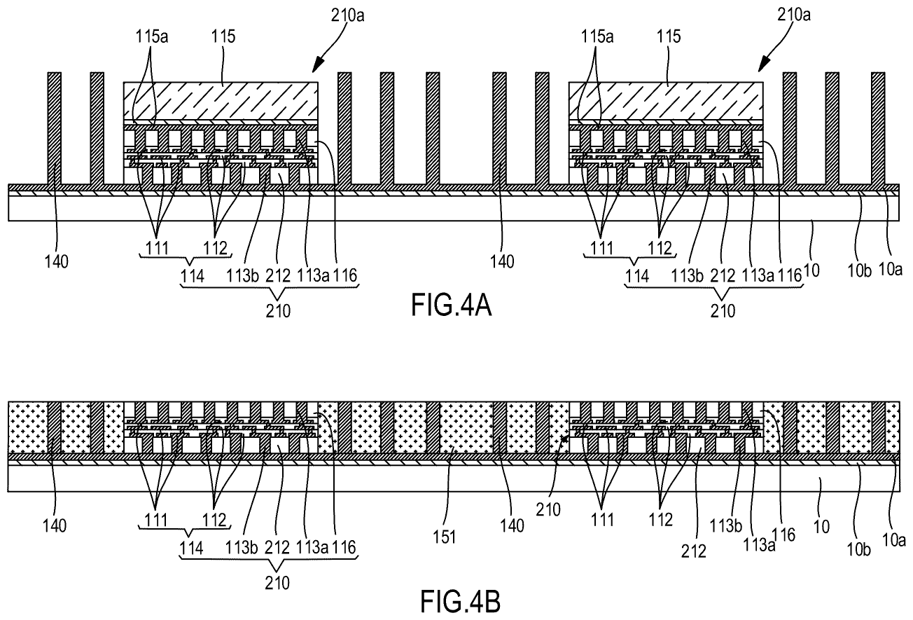

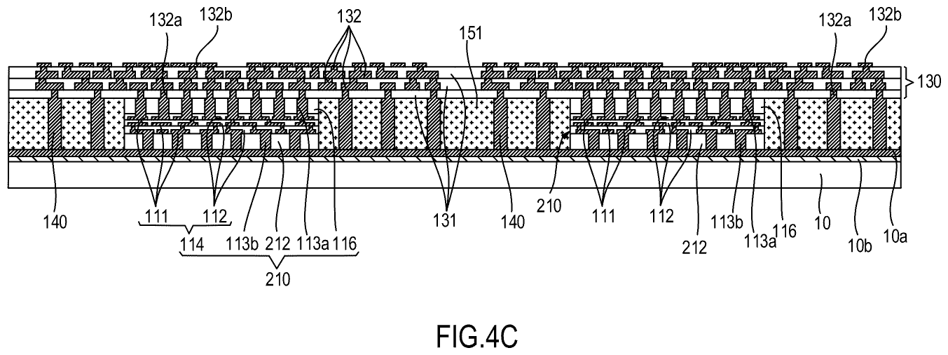

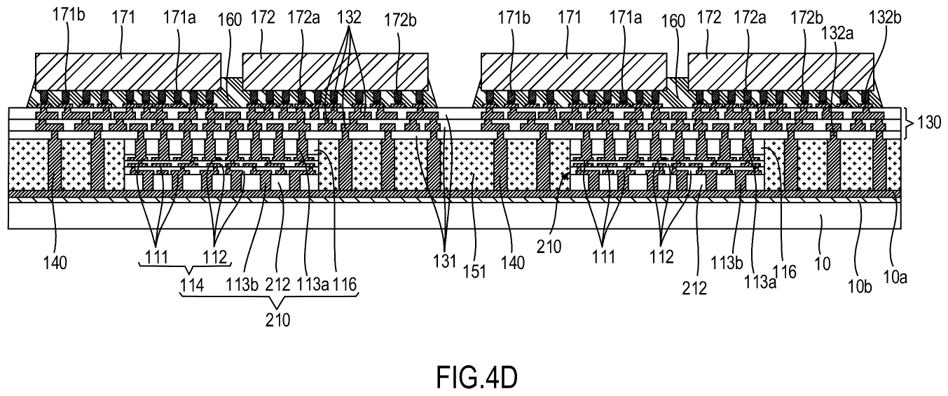

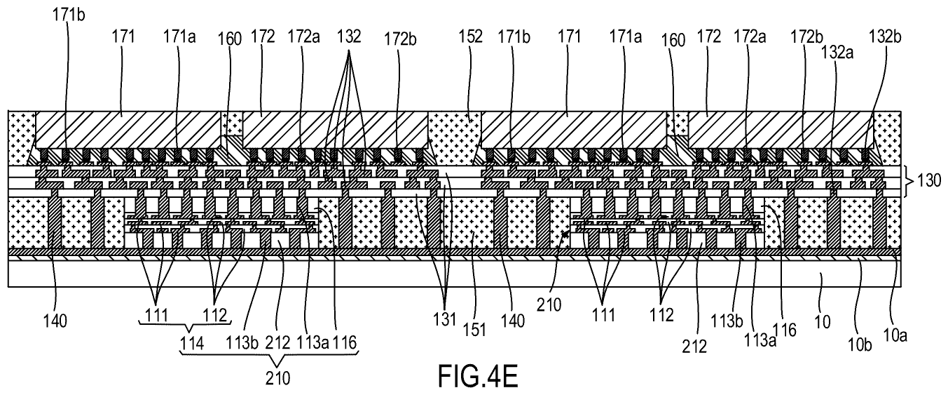

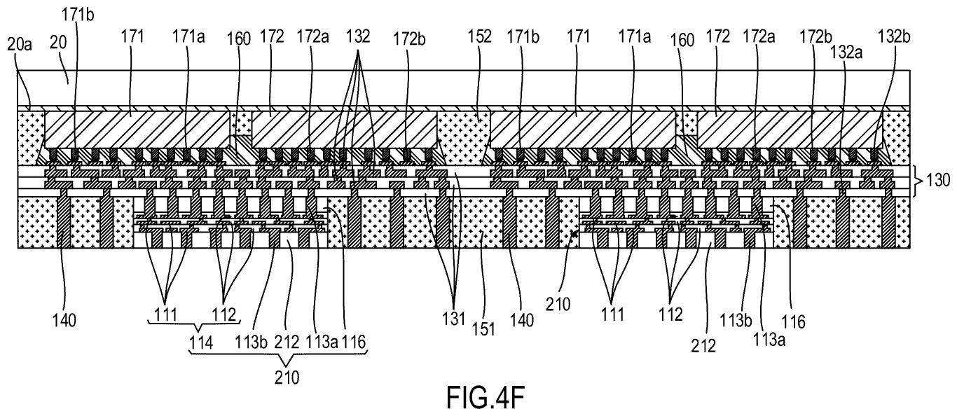

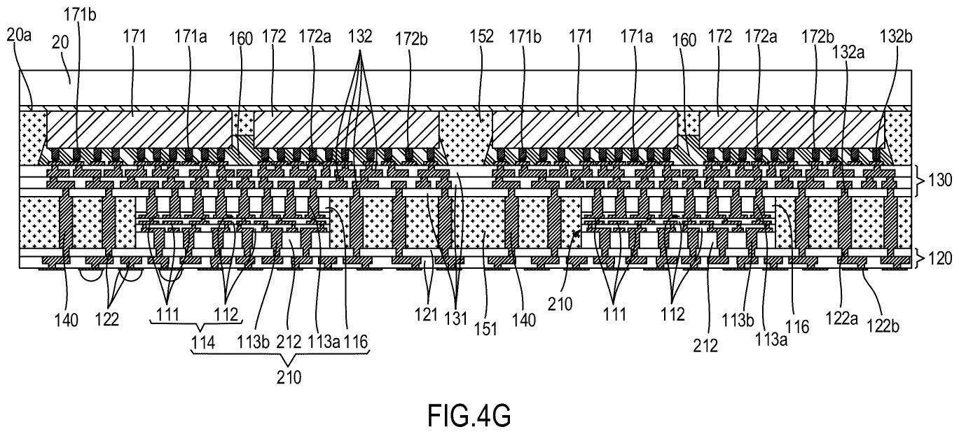

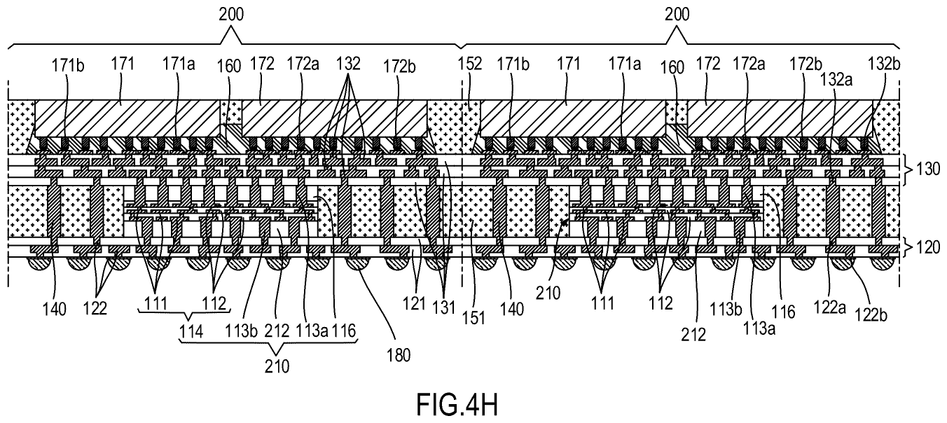

FIGS. 4A to 4H show cross-sectional views of an example method for manufacturing an example electronic device.

FIG. 4A shows a cross-sectional view of electronic device 200 at an early stage of manufacture. In the example shown in FIG. 4A, bridge assemblies 210a and internal interconnects 140 may be provided on the upper side of a first carrier 10.

The first carrier 10 and the internal interconnects 140 may have corresponding elements, features, materials, or manufacturing methods similar to those of the first carrier 10 and the internal interconnects 140 of electronic device 100. The bridge assembly 210a may also be similar to bridge assembly 110a of FIG. 2A. However, the bridge assembly 210a may comprise the bridge component 210 and may be flipped with respect to the bridge assembly 110a of FIG. 2A such that bridge base 115 is facing upward with bridge signal redistribution structure 114 located between bridge base 115 and first carrier 10.

In the bridge assembly 210a, the bridge base 115 may be located on the upper side of the bridge assembly 210a and the bridge component 210 can be proximate to the first carrier 10. In the bridge component 210, the signal redistribution dielectric structure 112 and the signal redistribution conductive structure 111 of the bridge signal redistribution structure 114 may be located on the lower side of the bridge base 115. The bridge assembly 210a may be bonded and secured to the upper side of the first carrier 10 through the lower bridge insulating body 212. The lower bridge insulating body 212 may be interposed between the signal redistribution dielectric structure 112 and the first carrier 10. The lower bridge insulating body 212 may surround the bridge second interconnects 113b. The lower bridge insulating body 212 may be in contact with respective sidewalls of the bridge second interconnects 113b. In some examples, the lower bridge insulating body 212 may comprise or be referred to as a nonconductive paste (NCP), a nonconductive film (NCF), an anisotropic conductive film (ACF), or an anisotropic conductive paste (ACP).

FIG. 4B shows a cross-sectional view of the electronic device 200 at a later stage of manufacture. In the example shown in FIG. 4B, the lower encapsulant 151 is provided over the bridge assemblies 210a (FIG. 4A) and the internal interconnects 140, and the bridge base 115 is removed from the bridge assemblies 210a.

In accordance with various examples, an upper portion of the lower encapsulant 151 may be removed to expose the upper sides of the bridge first interconnects 113a of the bridge component 210 and the upper sides of the internal interconnects 140. When the bridge base 115 is removed, the bridge component 210 may comprise bridge signal redistribution structure 114 and the lower bridge insulating body 212. The lower encapsulant 151 may contact the sidewall of the bridge component 210 and the sidewall of the internal interconnects 140. In some examples, the upper sides of the bridge first interconnects 113a, the upper sides of the internal interconnects 140, and the upper side of the lower encapsulant 151 may be coplanar. In some examples, the lower encapsulant 151 may have corresponding elements, features, materials, or manufacturing methods similar to those of the lower encapsulant 151 of the electronic device 100.

FIG. 4C shows a cross-sectional view of the electronic device 200 at a later stage of manufacture. In the example shown in FIG. 4C, the upper substrate 130 may be provided on the upper side of the lower encapsulant 151, the upper sides of the bridge first interconnects 113a, and the upper sides of the internal interconnects 140. The upper substrate conductive structure 132 of the upper substrate 130 may contact and/or be coupled to the upper sides of the bridge first interconnects 113a and/or the upper side of the internal interconnects 140. The upper substrate 130 may have corresponding elements, features, materials, or manufacturing methods similar to those of the upper substrate 130 of the electronic device 100.

FIG. 4D shows a cross-sectional view of the electronic device 200 at a later stage of manufacture. In the example shown in FIG. 4D, the electronic components 171, 172 and the underfill 160 may be provided on the upper side of the upper substrate 130. The electronic components 171, 172 and the underfill 160 may have corresponding elements, features, materials, or manufacturing methods similar to those of the electronic component 171, 172 and the underfill 160 of the electronic device 100.

FIG. 4E shows a cross-sectional view of the electronic device 200 at a later stage of manufacture. In the example shown in FIG. 4E, the upper encapsulant 152 may cover the upper side of the upper substrate 130, the underfill 160, and the electronic components 171, 172. The upper encapsulant 152 may have corresponding elements, features, materials, or manufacturing methods similar to those of the upper encapsulant 152 of the electronic device 100.

FIG. 4F shows a cross-sectional view of the electronic device 200 at a later stage of manufacture. In the example shown in FIG. 4F, second carrier 20 is located on the upper sides of the electronic components 171, 172 and the upper side of the upper encapsulant 152, and internal interconnects 140 and the bridge second interconnects 113b are exposed.

In accordance with various examples, after the second carrier 20 is located on the upper sides of the electronic components 171, 172 and the upper side of the upper encapsulant 152, a lower portion of the bridge component 210, a lower portion of the internal interconnects 140, and a lower portion of the lower encapsulant 151 may be removed. Before removing the lower portion of the bridge component 210, the lower portion of the internal interconnects 140, and the lower portion of the lower encapsulant 151, the first carrier 10 may be removed from the lower sides of the lower encapsulant 151, the lower side of the bridge component 210, and the lower sides of the internal interconnects 140. The second carrier 20 may have corresponding elements, features, materials, or manufacturing methods similar to those of the second carrier 20 used to manufacture the electronic device 100. The method of removing the first carrier 10 may be similar to the method of removing the first carrier 10 used to manufacture the electronic device 100.

The lower portion of the lower encapsulant 151, the lower portion of the internal interconnects 140, and the lower portion of the bridge component 210 may be partially removed through grinding and/or etching. The lower sides of the internal interconnects 140, the lower sides of the bridge second interconnects 113b, and the lower side of lower bridge insulating body 212 may be exposed from a lower side of the lower encapsulant 151. The bridge signal redistribution structure 114 via its signal redistribution conductive structure 111 may provide signal transmission between the bridge first interconnects 113a along the upper side of the bridge component 210 and the bridge second interconnects 113b along the lower side of the bridge component 210. The heights of the bridge component 210, the lower encapsulant 151, and the internal interconnects 140 may be equal or approximately equal.

FIG. 4G shows a cross-sectional view of the electronic device 200 at a later stage of manufacture. In the example shown in FIG. 4G, the lower substrate 120 is provided over the lower encapsulant 151, the lower sides of the internal interconnects 140, and the lower side of bridge component 210. In accordance with various examples, lower substrate 120 may cover the lower side of the lower encapsulant 151, the lower sides of the internal interconnects 140, and the lower side of bridge component 210. The lower substrate 120 may have corresponding elements, features, materials, or manufacturing methods similar to those of the lower substrate 120 of the electronic device 100.

FIG. 4H shows a cross-sectional view of the electronic device 200 at a later stage of manufacture. In the example shown in FIG. 4H, the external interconnects 180 may be provided along the lower side of the lower substrate 120 and singulation can be performed to provide individual, discrete electronic devices 200. The external interconnects 180 may have corresponding elements, features, materials, or manufacturing methods similar to those of the external interconnects 180 of the electronic device 100.

In summary, various examples of electronic device with bridge components are disclosed. The bridge components may include signal redistribution structure that provide electrical paths for providing signals, power, and/or ground to electronic components and between electronic components of the electronic device. In some embodiments, the bridge component includes a bridge die that is removed during manufacture.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. A method of manufacturing an electronic device, the method comprising:
providing internal interconnects and a bridge assembly, wherein the bridge assembly comprises a bridge base and a bridge signal redistribution structure;
encapsulating the internal interconnects and the bridge assembly in a lower encapsulant;
removing the bridge base from the bridge assembly;
covering an upper side of the lower encapsulant with an upper substrate such that an upper substrate conductive structure is coupled to the internal interconnects and to the bridge signal redistribution structure;
coupling, via the upper substrate, first interconnects of a first electronic component to the bridge signal redistribution structure and second interconnects of the first electronic component to the internal interconnects; and
coupling, via the upper substrate, first interconnects of a second electronic component to the bridge signal redistribution structure and second interconnects of the second electronic component to the internal interconnects.

2. The method of claim 1, wherein the removing the bridge base comprises grinding lower sides of the internal interconnects, a lower side of the lower encapsulant, and a lower side of the bridge assembly to remove a lower portion of the internal interconnects, a lower portion of the lower encapsulant, and a lower portion of the bridge assembly.

3. The method of claim 2, wherein the lower portion of the bridge assembly includes the bridge base.

4. The method of claim 1, wherein the removing the bridge base comprises grinding upper sides of the internal interconnects, an upper side of the lower encapsulant, and an upper side of the bridge assembly to remove an upper portion of the internal interconnects, an upper portion of the lower encapsulant, and an upper portion of the bridge assembly.

5. The method of claim 4, wherein the upper portion of the bridge assembly includes the bridge base.

6. The method of claim 1, wherein the removing the bridge base comprises etching lower sides of the internal interconnects, a lower side of the lower encapsulant, and a lower side of the bridge assembly to remove a lower portion of the internal interconnects, a lower portion of the lower encapsulant, and a lower portion of the bridge assembly.

7. The method of claim 6, wherein the lower portion of the bridge assembly includes the bridge base.

8. The method of claim 1, wherein the removing the bridge base comprises etching upper sides of the internal interconnects, an upper side of the lower encapsulant, and an upper side of the bridge assembly to remove an upper portion of the internal interconnects, an upper portion of the lower encapsulant, and an upper portion of the bridge assembly.

9. The method of claim 8, wherein the upper portion of the bridge assembly includes the bridge base.

10. The method of claim 1, wherein coupling the first interconnects of the first electronic component to the bridge signal redistribution structure and coupling the first interconnects of the second electronic component to the bridge signal redistribution structure couples one or more of the first interconnects of the first electronic component to one or more of the first interconnects of the second electronic component.

11. The method of claim 1, comprising providing external interconnects coupled to lower sides of the internal interconnects.

12. The method of claim 1, comprising covering a lower side of the lower encapsulant with a lower substrate such that a lower substrate conductive structure is coupled to the internal interconnects and the bridge signal redistribution structure.

13. The method of claim 12, comprising providing external interconnects coupled to lower sides of the internal interconnects via the lower substrate.

14. The method of claim 1, comprising encapsulating the first electronic component and the second electronic component in an upper encapsulant.

15. The method of claim 1, comprising providing an underfill between a lower side of the first electronic component and an upper side of the upper substrate.

16. An electronic device, comprising:
a lower substrate comprising an upper side and a lower side;
an upper substrate comprising an upper side and a lower side;
internal interconnects that couple the upper side of the lower substrate to the lower side of the upper substrate;
a bridge component comprising bridge first interconnects coupled to the lower side of the upper substrate, bridge second interconnects coupled to the upper side of the lower substrate, a bridge signal redistribution structure coupled to the bridge first interconnects and the bridge second interconnects; and
a lower encapsulant that encapsulates the internal interconnects and the bridge component;
a first electronic component coupled to the internal interconnects and the bridge signal redistribution structure via the upper side of the upper substrate; and
a second electronic component coupled to the internal interconnects and the bridge signal redistribution structure via the upper side of the upper substrate; and
wherein the bridge signal redistribution structure provides one or more signal paths between the first electronic component and the second electronic component.

17. The electronic device of claim 16, comprising first external interconnects coupled to lower sides of the internal interconnects via the lower substrate.

18. The electronic device of claim 17, comprising second external interconnects coupled to bridge second interconnects via the lower substrate.

19. The electronic device of claim 16, comprising an upper encapsulant that encapsulates the first electronic component and the second electronic component.

20. The electronic device of claim 19, comprising:
an underfill between a lower side of the first electronic component and an upper side of the upper substrate; and
wherein the upper encapsulant encapsulates and contacts the underfill.
